(19) United States
(12) Patent Application Publication
(10) Pub. No.: US 2017/0076958 A1
(43) Pub. Date: Mar. 16, 2017

(54) MANUFACTURING METHOD OF SEMICONDUCTOR DEVICE

(71) Applicant: Kabushiki Kaisha Toshiba, Minato-ku (JP)

(72) Inventor: Junya NISHIWAKI, Oshu (JP)

(73) Assignee: Kabushiki Kaisha Toshiba, Minato-ku (JP)

(21) Appl. No.: 15/254,314

(22) Filed: Sep. 1, 2016

(30) Foreign Application Priority Data
Sep. 11, 2015 (JP) 2015-179720

(51) Int. Cl. H01L 21/321; H01L 23/532; H01L 21/768

(52) U.S. Cl. CPC H01L 21/3212; H01L 21/76831; H01L 21/7684; H01L 21/76849; H01L 23/53238; H01L 23/5329

(57) ABSTRACT

Certain embodiments provide a manufacturing method of a semiconductor device including: forming a first through-hole in a first insulation film provided on a semiconductor substrate; embedding a first copper and a first barrier metal, in this order, into the first through-hole, an etching rate of the first barrier metal being equal to or more than an etching rate of the first insulation film; forming a second insulation film on the first barrier metal and the first insulation film; forming a second through-hole by removing, using etching, the second insulation film on the first barrier metal, the first barrier metal, and the first insulation film which is neighboring the first barrier metal; and embedding a second copper into the second through-hole.

### CROSS REFERENCE TO RELATED APPLICATIONS

This application is based upon and claims the benefit of priority from the prior Japanese Patent Application No. 2015-179720 filed in Japan on Sep. 11, 2015; the entire contents of which are incorporated herein by reference.

### FIELD

Embodiments described herein relate generally to manufacturing methods of semiconductor devices.

### BACKGROUND

Along with the advances in integration and speed of a semiconductor device equipped with a multilayer wiring layer, a reduction of parasitic capacitance between a lower layer wiring and an upper layer wiring of the semiconductor device is required. For this reason, a development of technology is required for reducing resistance of each wiring in the semiconductor device and for reducing dielectric constant of an inter-layer insulation layer which is between the lower layer wiring and the upper layer wiring.

Conventionally, as a wiring material of the semiconductor device, aluminum (Al) is applied. However, in view of reducing the resistance of the wiring, copper (Cu) is studied as a wiring material replacing the aluminum.

Nevertheless, when copper (Cu) is applied for a wiring material of the semiconductor device, there is a following problem. The connection wiring, which connects the lower layer wiring and the upper layer wiring, is provided so as to fill a through-hole provided in the inter-layer insulation layer. However, when the connection wiring is formed by single damascene process, the embedding property of copper (Cu), which will be the connection wiring, to the through-hole becomes insufficient. Thus, the reliability of the formed connection wiring degrades. As a result, the reliability of the semiconductor device equipped with the multilayer wiring layer degrades.

### BRIEF DESCRIPTION OF THE DRAWINGS

FIG. 1 is a sectional view illustrating an essential part of a semiconductor device manufactured by a manufacturing method of a semiconductor device according to a first embodiment;

FIG. 2A is a sectional view of a semiconductor device for illustrating the manufacturing method of the semiconductor device according to the first embodiment;

FIG. 2B is a sectional view of a semiconductor device for illustrating the manufacturing method of the semiconductor device according to the first embodiment;

FIG. 2C is a sectional view of a semiconductor device for illustrating the manufacturing method of the semiconductor device according to the first embodiment;

FIG. 2D is a sectional view of a semiconductor device for illustrating the manufacturing method of the semiconductor device according to the first embodiment;

FIG. 2E is a sectional view of a semiconductor device for illustrating the manufacturing method of the semiconductor device according to the first embodiment;

FIG. 2F is a sectional view of a semiconductor device for illustrating the manufacturing method of the semiconductor device according to the first embodiment;

FIG. 2G is a sectional view of a semiconductor device for illustrating the manufacturing method of the semiconductor device according to the first embodiment;

FIG. 2H is a sectional view of a semiconductor device for illustrating the manufacturing method of the semiconductor device according to the first embodiment;

FIG. 2I is a sectional view of a semiconductor device for illustrating the manufacturing method of the semiconductor device according to the first embodiment;

FIG. 2J is a sectional view of a semiconductor device for illustrating the manufacturing method of the semiconductor device according to the first embodiment;

FIG. 2K is a sectional view of a semiconductor device for illustrating the manufacturing method of the semiconductor device according to the first embodiment;

FIG. 3 is a sectional view illustrating an essential part of a semiconductor device manufactured by a manufacturing method of a semiconductor device according to a second embodiment;

FIG. 4A is a sectional view of a semiconductor device for illustrating the manufacturing method of the semiconductor device according to the second embodiment;

FIG. 4B is a sectional view of a semiconductor device for illustrating the manufacturing method of the semiconductor device according to the second embodiment;

FIG. 4C is a sectional view of a semiconductor device for illustrating the manufacturing method of the semiconductor device according to the second embodiment;

FIG. 4D is a sectional view of a semiconductor device for illustrating the manufacturing method of the semiconductor device according to the second embodiment; and

FIG. 4E is a sectional view of a semiconductor device for illustrating the manufacturing method of the semiconductor device according to the second embodiment.

### DETAILED DESCRIPTION

Certain embodiments provide a manufacturing method of a semiconductor device including: forming a first through-hole in a first insulation film provided on a semiconductor substrate; embedding a first copper and a first barrier metal, in this order, into the first through-hole, an etching rate of the first barrier metal being equal to or more than an etching rate of the first insulation film; forming a second insulation film on the first barrier metal and the first insulation film; forming a second through-hole by removing, using etching, the second insulation film on the first barrier metal, the first barrier metal, and the first insulation film which is neighboring the first barrier metal; and embedding a second copper into the second through-hole.

Certain embodiments provide a manufacturing method of a semiconductor device including: forming a first insulation film and a first etching stopper film, in this order, on a semiconductor substrate; forming a first through-hole in the first etching stopper film and the first insulation film; embedding a first copper and a first barrier metal, in this order, into the first through-hole, an etching rate of the first barrier metal being equal to or more than an etching rate of the etching stopper film and the first insulation film; forming a second insulation film on the first barrier metal and the first etching stopper film; forming a second through-hole by removing, using etching, the second insulation film on the first barrier metal, the first barrier metal, and the first etching stopper film and the first insulation film which are neighboring the first barrier metal; and embedding a second copper into the second through-hole.

The manufacturing method of the semiconductor device according to the embodiments will be detailed below with reference to drawings.

### First Embodiment

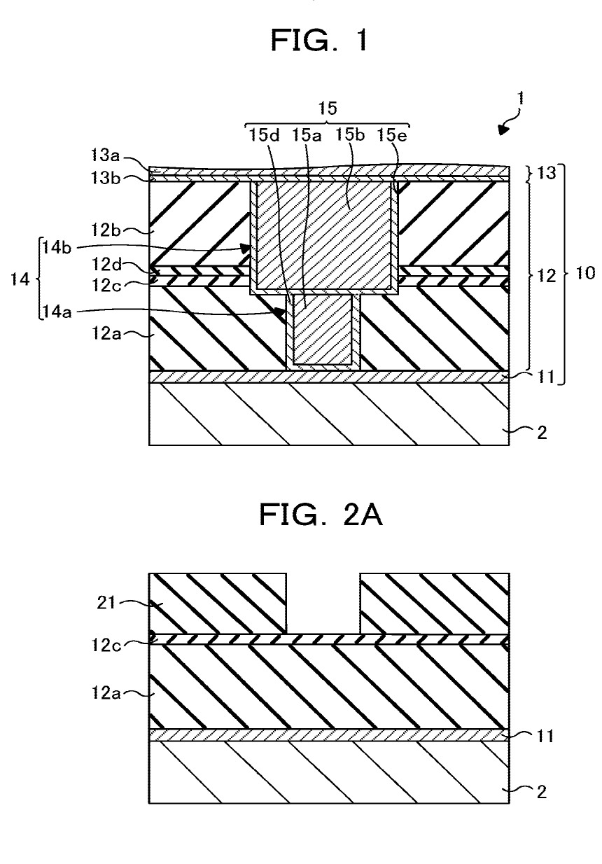

FIG. 1 is a sectional view illustrating an essential part of a semiconductor device manufactured by a manufacturing method of a semiconductor device according to the first embodiment. In a semiconductor device 1 illustrated in FIG. 1, a multilayer wiring layer 10 is provided on the upper surface of a semiconductor substrate 2 made of, for example, silicon. The multilayer wiring layer 10 includes a lower layer wiring 11, an inter-layer insulation layer 12, and an upper layer wiring 13.

The lower layer wiring 11 of the multilayer wiring layer 10 has a predetermined pattern which is provided above the upper surface of the semiconductor substrate 2. The lower layer wiring 11 is made of copper (Cu) for reducing the resistance of the wiring. As illustrated in FIG. 1 or the like, the lower layer wiring 11 is provided so as to contact the upper surface of the semiconductor substrate 2. However, an interlayer insulation film can be provided between the semiconductor substrate 2 and the lower layer wiring 11.

On the upper surface of the semiconductor substrate 2, which includes the lower layer wiring 11, the inter-layer insulation layer 12 is provided. The inter-layer insulation layer 12 is made by laminating multiple insulation films. In this embodiment, the inter-layer insulation layer 12 is made by laminating two-layered insulation films (first insulation film 12a, and second insulation film 12b). Each of the insulation films 12a and 12b is made of films such as SiO₂ film or SiOC film.

Between the upper surface of the semiconductor substrate 2, which includes the lower layer wiring 11, and the inter-layer insulation layer 12, a barrier layer (not illustrated) made of, for example, Si₃N₄ or SiC can be provided.

The barrier layer prevents copper (Cu), which is a metal constituting the lower layer wiring 11, from spreading to the first insulation film 12a.

Between the first insulation film 12a and the second insulation film 12b, at least one layer of an etching stopper layer can be provided. In this embodiment, a first etching stopper film 12c and a second etching stopper film 12d are laminated, in this order, between the first insulation film 12a and the second insulation film 12b. Each of the etching stopper films 12c and 12d is made of film such as SiN film or SiC film.

In such inter-layer insulation layer 12, a through-hole that penetrates this layer 12 is provided. The through-hole 14 is provided on the upper surface of the lower layer wiring 11 such that the upper surface of the lower layer wiring 11 is exposed inside the through-hole 14.

Inside the through-hole 14, a connection wiring 15 is provided for connecting the lower layer wiring 11 and the upper layer wiring 13 (discussed later). The connection wiring 15 is provided so as to be embedded into the through-hole 14 and to contact the upper surface of the lower layer wiring 11. Similarly to the lower layer wiring 11, this connection wiring 15 is made mainly of copper (Cu) for reducing the resistance of the wiring. However, a first barrier metal 15c (not illustrated in FIG. 1), which is a sacrifice layer, can be included as apart of the connection wiring 15. The connection wiring 15 can include a second barrier metal 15d and a third barrier metal 15e as apart of it. The second and third barrier metals 15d and 15e can improve the adhesion property between the inter-layer insulation layer 12 and a metal such as copper (Cu) which will be the connection wiring 15. Each of the first to third barrier metals 15c, 15d, and 15e is made of, for example, tantalum nitride (TaN).

On the upper surface of the inter-layer insulation layer 12 provided with such connection wiring 15, the upper layer wiring 13 is provided so as to contact the upper surface of the connection wiring 15. Similarly to the lower layer wiring 11, the upper layer wiring 13 is a predetermined pattern provided on the upper surface of the inter-layer insulation layer 12. The upper layer wiring 13 is made of copper (Cu) for reducing the resistance of the wiring. Similarly to the connection wiring 15, the upper layer wiring 13 can be constituted by a main wiring 13a made of, for example, copper (Cu), and a fourth barrier metal 13b. The fourth barrier metal 13b can improve the adhesion property between the inter-layer insulation layer 12 and the main wiring 13a.

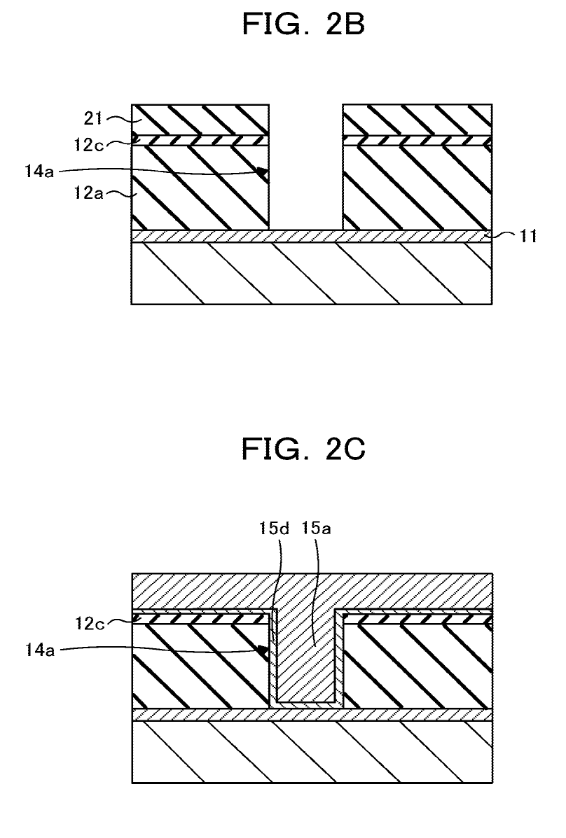

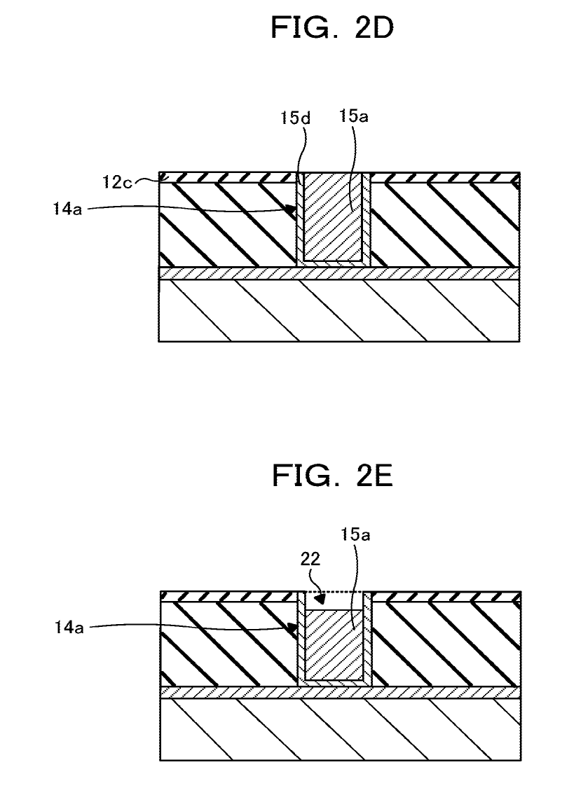

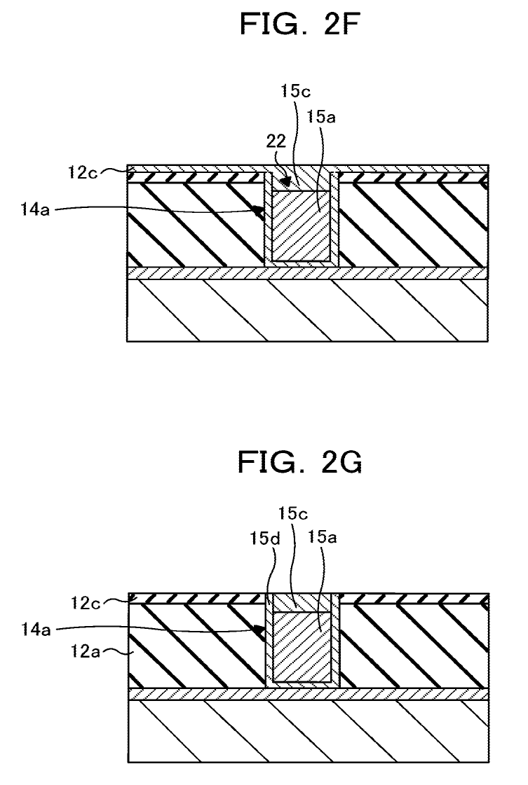

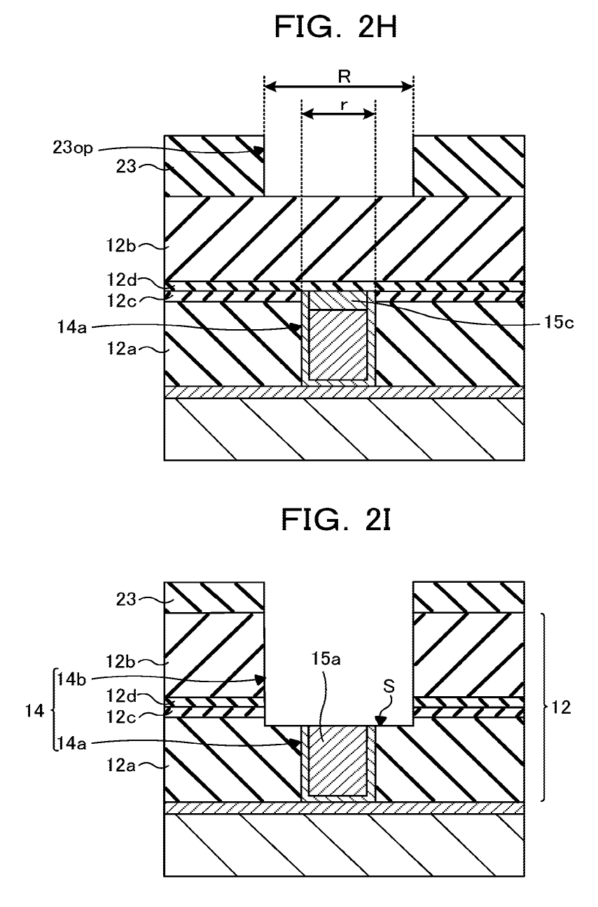

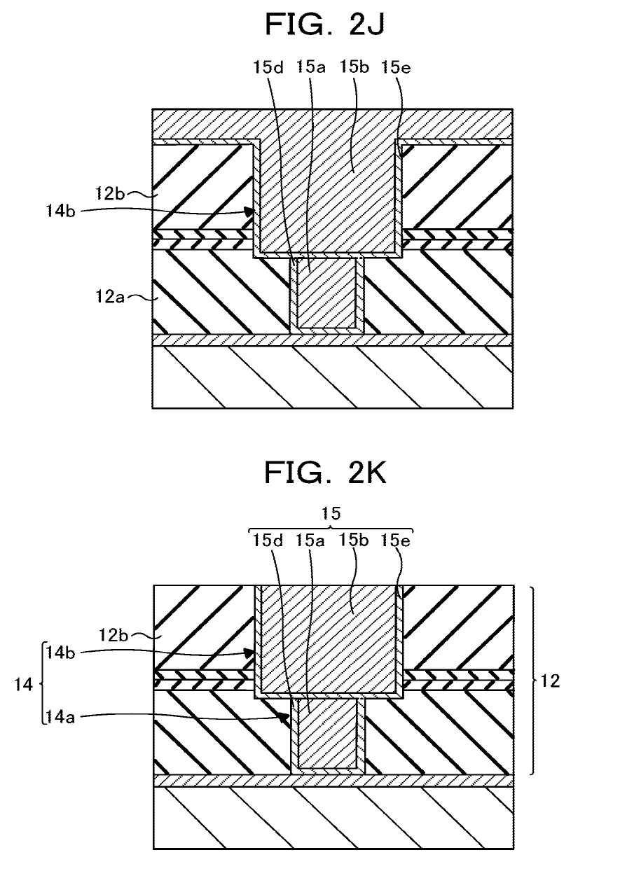

As a manufacturing method of the semiconductor device according to the first embodiment, a manufacturing method of the semiconductor device 1 equipped with the multilayer wiring layer 10 will be discussed below with reference to FIG. 2A to FIG. 2K. Each of the FIG. 2A to FIG. 2K is a sectional view of a semiconductor device for illustrating the manufacturing method of the semiconductor device according to the first embodiment.

First, as illustrated in FIG. 2A, the first insulation film 12a and the first etching stopper film 12c are formed, in this order, on the upper surface of the semiconductor substrate 2 formed beforehand with the lower layer wiring 11. In this embodiment, the semiconductor substrate 2 is, for example, a silicon substrate, and the lower layer wiring 11 is a metal wiring made mainly of copper. The first insulation film 12a is made of SiO₂ film or SiOC film. The first etching stopper film 12c is made of SiN film or SiC film. The first insulation film 12a can be formed on the upper surface of the semiconductor substrate 2 via the barrier layer (not illustrated) which is made of Si₃N₄ or SiC.

Furthermore, a SiCN layer, which will be a hard mask, is formed on the upper surface of the first etching stopper film 12c, and a photoresist pattern is formed on the upper surface of the SiCN layer. Then, a SiCN layer is processed by reactive ion etching (RIE) using a photoresist pattern, and the photoresist pattern is exfoliated by ashing. Thus, a hard mask 21 is formed on the upper surface of the first etching stopper film 12c.

Next, as illustrated in FIG. 2B, a first through-hole 14a is formed by removing the first etching stopper film 12c and the first insulation film 12a with RIE using the hard mask 21. In the RIE, a mixed gas including CH₂F₂, CF₄, Ar, N₂, and the like is used. From the first through-hole 14a, the lower layer wiring 11 is exposed.

After the removal of the hard mask 21, as illustrated in FIG. 2C, a first copper 15a is formed on the upper surface of the first etching stopper film 12c via the second barrier metal 15d, so that the first copper 15a and the second barrier metal 15d are embedded into the first through-hole 14a. The second barrier metal 15d allows improving the adhesion property between the first insulation film 12a and the first copper 15a. The first copper 15a will be the main wiring of the connection wiring 15. In this embodiment, the second barrier metal 15d is, for example, tantalum nitride (TaN).

Thereafter, as illustrated in FIG. 2D, unnecessary second barrier metal 15d and first copper 15a on the first etching stopper film 12c are removed using chemical mechanical polishing (CMP) method. The upper surface of the first etching stopper film 12c, where the second barrier metal 15d and the first copper 15a are exposed locally, is flattened. Therefore, the first copper 15a is embedded only into the first through-hole 14a via the second barrier metal 15d.

Next, as illustrated in FIG. 2E, the upper layer of the first copper 15a is removed by wet etching to form a space 22 inside the first through-hole 14a.

Next, as illustrated in FIG. 2F, the first barrier metal 15c, which is a sacrifice layer, is formed on the upper surface of the first etching stopper film 12c so as to fill the space 22 generated inside the first through-hole 14a by removing the upper layer of the first copper 15a.

Then, as illustrated in FIG. 2G, unnecessary first barrier metal 15c on the first etching stopper film 12c is removed using CMP method. The upper surface of the first etching stopper film 12c, where the first barrier metal 15c is exposed locally, is flattened again. Therefore, the first copper 15a is embedded only into the first through-hole 14a via the second barrier metal 15d, and the first barrier metal 15c is also embedded only into the first through-hole 14a via the second barrier metal 15d.

Hereafter, the etching rate of the first barrier metal 15c will be referred to as ER_{BM}, under an etching condition for forming a second through-hole 14b (FIG. 2I) which is discussed later. The etching rate of the first etching stopper film 12c and the first insulation film 12a will be referred to as ER_{I}. In this case, the first barrier metal 15c is made of a metal material satisfying ER_{BM}≧ER_{I}. For example, when the first etching stopper film 12c is SiN film or SiC film, and the first insulation film 12a is SiO₂ film or SiOC film, tantalum nitride (TaN) or tantalum (Ta) can be applied for the first barrier metal 15c. On condition that these materials are selected, the relationship between the ER_{BM} and the ER_{I} can be controlled to ER_{BM}=ER_{I} or to ER_{BM}>ER_{I} by changing the etching condition of the etching gas.

Thereafter, as illustrated in FIG. 2H, the second etching stopper film 12d and the second insulation film 12b are formed, in this order, on the upper surface of the first etching stopper film 12c where the first barrier metal 15c is exposed. Similarly to the first etching stopper film 12c, the second etching stopper film 12d is made of SiN film or SiC film. Similarly to the first insulation film 12a, the second insulation film 12b is made of SiO₂ film or SiOC film.

Furthermore, a SiCN layer, which will be a hard mask 23, is formed on the upper surface of the second insulation film 12b, and a photoresist pattern is formed on the upper surface of the SiCN layer. Then, the SiCN layer is processed by reactive ion etching (RIE) using the photoresist pattern, and the photoresist pattern is exfoliated by ashing. Thus, the hard mask 23 is formed on the upper surface of the second insulation film 12b. An opening pattern 23op of the hard mask 23 has the opening diameter R that is larger than a opening diameter r of the first through-hole 14a, and is provided above the first barrier metal 15c.

Next, as illustrated in FIG. 2I, a second through-hole 14b is formed by removing, with etching using the hard mask 23, the second insulation film 12b, the second etching stopper film 12d, the first etching stopper film 12c, and the first insulation film 12a. The etching is performed under an etching condition substantially satisfying ER_{BM}=ER_{I} (for example, RIE using chlorine based gas). The etching for forming the second through-hole 14b is performed until the upper surface of the first copper 15a, which is embedded into the first through-hole 14a, is exposed in the second through-hole 14b.

The etching for forming the second through-hole 14b can be performed so that the first barrier metal 15c is exposed from the second through-hole 14b. In other words, the first barrier metal 15c does not have to be removed entirely.

This etching process allows forming the through-hole 14, constituted by the first through-hole 14a and the second through-hole 14b, in the inter-layer insulation layer 12.

When the first etching stopper film 12c and the first insulation film 12a are removed during the etching, at least a part of the first barrier metal 15c, which is a sacrifice layer, is also removed. Here, the first barrier metal 15c is made of metal satisfying the condition ER_{BM}≧ER_{I}. Therefore, the second through-hole 14b is formed by etching under an etching condition substantially satisfying ER_{BM}=ER_{I}. Thus, the first copper 15a or the first barrier metal 15c, which are embedded into the first through-hole 14a, can be prevented from projecting convexly inside the second through-hole 14b. Therefore, the upper surfaces of the first copper 15a or the first barrier metal 15c can be in flush with the upper surface of the first insulation film 12a. In other words, a plane S having substantially no steps is exposed from the second through-hole 14b, where the upper surfaces of the first copper 15a or the first barrier metal 15c is in flush with the upper surface of the first insulation film 12a.

Next, as illustrated in FIG. 2J, a second copper 15b is formed on the upper surface of the second insulation film 12b so as to be embedded into the second through-hole 14b via the third barrier metal 15e. The third barrier metal 15e allows improving the adhesion property between the second insulation film 12b and the second copper 15b. The second copper 15b will be the main wiring of the connection wiring 15. In this embodiment, the third barrier metal 15e is, for example, tantalum nitride (TaN) similarly to the second barrier metal 15d.

Here, the plane S is exposed from the second through-hole 14b (FIG. 2I). This prevents from forming a space inside the second through-hole 14b when the second copper 15b is embedded into the second through-hole 14b via the third barrier metal 15e.

On the contrary, when the second through-hole is formed, while the entire first through-hole is embedded with the first copper only, a step occurs in a surface exposed from the second through-hole. This is because the first copper is projected convexly inside the second through-hole since the etching rate of the copper is slower than the etching rates of the first etching stopper film and the first insulation film.

Therefore, a space is formed inside the second through-hole when the third barrier metal and the second copper are embedded into the second through-hole because these metals are not embedded properly. This degrades the reliability of the connection wiring and becomes one of the factors for degrading the reliability of the semiconductor device equipped with the multilayer wiring layer.

Thereafter, as illustrated in FIG. 2K, unnecessary third barrier metal 15e and the second copper 15b on the second insulation film 12b are removed using CMP method. The upper surface of the second insulation film 12b, where the third barrier metal 15e and the second copper 15b are exposed locally, is flattened. Therefore, the second copper 15b is embedded only into the second through-hole 14b via the third barrier metal 15e. The connection wiring 15 is then formed in the through-hole 14 of the inter-layer insulation layer 12.

After the formation of the connection wiring 15, the upper layer wiring 13 made of copper, for example, is formed on the upper surface of the second insulation film 12b which includes the upper surface of the connection wiring 15 (the upper surface of the second copper 15b). The upper layer wiring 13 is constituted so as to contact the upper surface of the connection wiring 15 (the upper surface of the second copper 15b). The upper layer wiring 13 can be constituted by the main wiring 13a made of, for example, copper (Cu) and the fourth barrier metal 13b made of, for example, tantalum nitride (TaN). The fourth barrier metal 13b allows improving the adhesion property between the inter-layer insulation layer 12 and the main wiring 13a. The semiconductor device 1 illustrated in FIG. 1 is thereby manufactured.

As discussed above, according to the manufacturing method of the semiconductor device 1 of the first embodiment, the first barrier metal 15c satisfying the condition ER_{BM}≧ER_{I} is formed in the upper part of the first through-hole 14a. The first through-hole 14a is provided in the first etching stopper film 12c and the first insulation film 12a. On condition that such first barrier metal 15c is formed, the second through-hole 14b is formed by an etching with etching condition substantially satisfying ER_{BM}=ER_{I}. Therefore, the plane S having no steps can be exposed from the second through-hole 14b. The second copper 15b can be embedded into the second through-hole 14b, where such plane S is exposed, via the third barrier metal 15e. As a result, the connection wiring 15 is prevented from including the space. Therefore, the connection wiring 15 with high reliability can be formed, and the semiconductor device 1 with high reliability can be manufactured.

### Second Embodiment

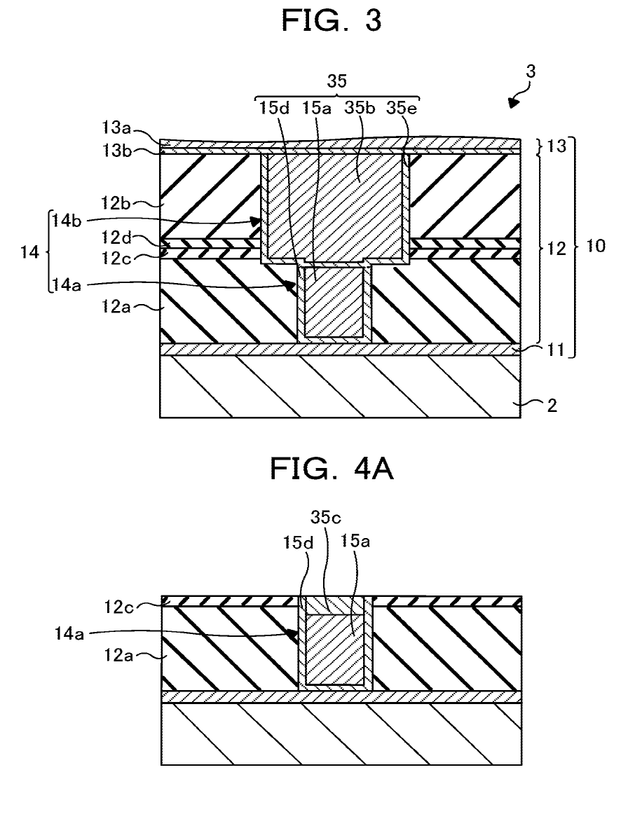

FIG. 3 is a sectional view illustrating an essential part of a semiconductor device manufactured by a manufacturing method of a semiconductor device according the second embodiment. In the semiconductor device 3 illustrated in FIG. 3, same reference numbers are assigned to portions that are same as the semiconductor device 1 illustrated in FIG. 1. In the following discussion regarding a semiconductor devices 3, the explanations are omitted for portions common to the semiconductor device 1 illustrated in FIG. 1.

Compared with the semiconductor device 1 illustrated in FIG. 1, the semiconductor device 3 illustrated in FIG. 3 differs in that the bottom surface of a second copper 35b, constituting a connection wiring 35, is convex downward. In conjunction with this, the geometry of a third barrier metal 35e, formed along the bottom surface of the second copper 35b, is convex downward. The material constituting the third barrier metal 35e is similar to that of the first embodiment.

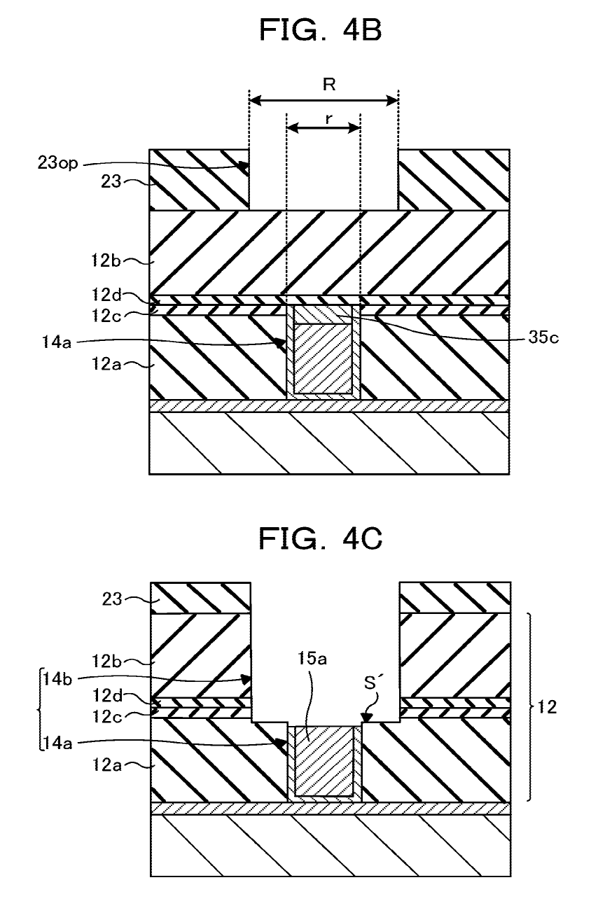

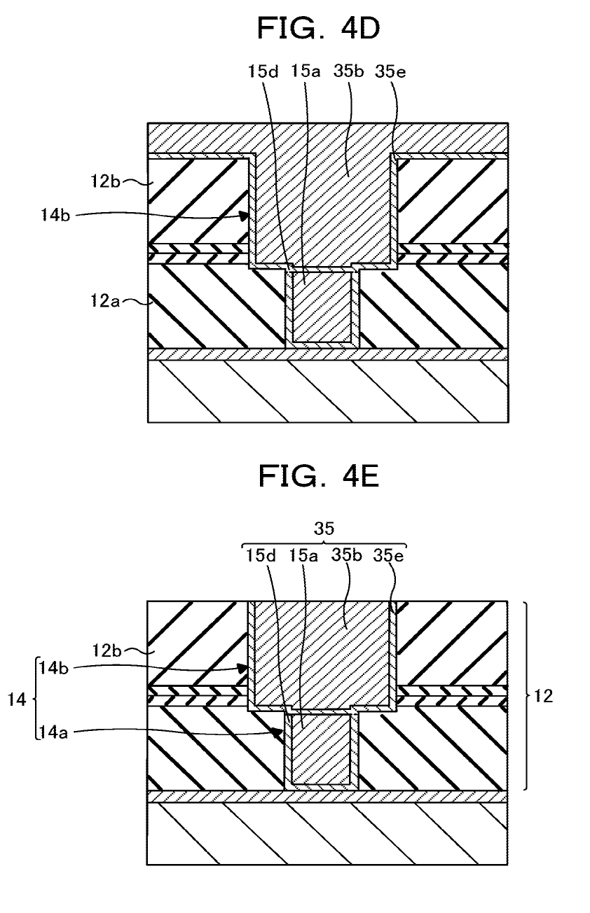

The manufacturing method of this semiconductor device 3 will be discussed with reference to FIG. 4A to FIG. 4E. In the following discussion regarding the manufacturing method of the semiconductor devices 3 according to the second embodiment, the explanation is omitted for the processes common to the manufacturing method of the semiconductor device 1 according to the first embodiment.

First, the space 22 is formed on the upper surface of the first copper 15a in the inside of the first through-hole 14a by performing the processes similar to FIG. 2A to FIG. 2E.

In the beginning, the first insulation film 12a and the first etching stopper film 12c are formed, in this order, on the upper surface of the semiconductor substrate 2 formed beforehand with the lower layer wiring 11. Then the first through-hole 14a is formed in the first etching stopper film 12c and the first insulation film 12a so that the lower layer wiring 11 is exposed (FIG. 2A, FIG. 2B).

The first copper 15a is then embedded into the formed first through-hole 14a via the second barrier metal 15d (FIG. 2C, FIG. 2D). Then, the upper layer of the first copper 15a is removed by wet etching, and the space 22 is formed inside the first through-hole 14a (FIG. 2E).

Next, as illustrated in FIG. 4A, a first barrier metal 35c, which is a sacrifice layer, is formed on the upper surface of the first etching stopper film 12c. The first barrier metal 35c is formed so as to fill the space 22 (FIG. 2E) inside the first through-hole 14a generated by removing the upper layer of the first copper 15a. Then, unnecessary first barrier metal 35c on the first etching stopper film 12c is removed using CMP method, and the upper surface of the first etching stopper film 12c, where the first barrier metal 35c is exposed locally, is flattened.

In this embodiment, a metal material similar to the first barrier metal 15c, which is applied in the first embodiment, is used as the first barrier metal 35c.

Then, as illustrated in FIG. 4B, the second etching stopper film 12d and the second insulation film 12b are formed, in this order, on the upper surface of the first etching stopper film 12c where the first barrier metal 35c is exposed similarly to the first embodiment. Furthermore, the hard mask 23 having a predetermined opening pattern 23op is formed on the upper surface of the second insulation film 12b. The opening pattern 23op of the hard mask 23 has an opening diameter R that is larger than the opening diameter r of the first through-hole 14a, and is provided above the first barrier metal 35c.

Next, as illustrated in FIG. 4C, the second through-hole 14b is formed by removing, with etching using the hard mask 23, the second insulation film 12b, the second etching stopper film 12d, the first etching stopper film 12c, and the first insulation film 12a. The etching is performed with an etching condition satisfying ER_{BM}>ER_{I} (for example, RIE using a mixed gas of chlorine based gas and fluorine based gas). The etching for forming the second through-hole 14b is performed until the upper surface of the first copper 15a, embedded in the first through-hole 14a, is exposed into the second through-hole 14b.

The etching for forming the second through-hole 14b can be performed so that a part of the first barrier metal 35c remains on the upper surface of the first copper 15a. The first barrier metal 35c does not have to be removed entirely.

In this etching, at least a part of the first barrier metal 35c, which is a sacrifice layer, is also removed when the first etching stopper film 12c and first insulation film 12a are removed. Here, the first barrier metal 35c is made of metal satisfying the condition ER_{BM}≧ER_{I}. Therefore, the second through-hole 14b is formed with etching under an etching condition satisfying ER_{BM}>ER_{I}. The first copper 15a or the first barrier metal 35c, embedded in the first through-hole 14a, is thereby prevented from projecting convexly inside the second through-hole 14b. The upper surface of the first copper 15a or the first barrier metal 35c is formed below the upper surface of the first insulation film 12a. From the second through-hole 14b, a concaved surface S′ is exposed. Here, the concaved surface S′ includes: the upper surface of the first insulation film 12a; and the upper surface of the first copper 15a formed below the upper surface of the first insulation film 12a, or the upper surface of the first barrier metal 35c.

The concaved surface S′ is thus exposed from the second through-hole 14b. Therefore, the copper can be easily embedded without a crevice in the second through-hole 14b compared with the case where the copper is projected convexly. This prevents from forming a space inside the second through-hole 14b when the third barrier metal 35e and the second copper 35b are embedded into the second through-hole 14b in the next process.

Next, as illustrated in FIG. 4D, the second copper 35b is formed on the upper surface of the second insulation film 12b via the third barrier metal 35e so as to be embedded into the second through-hole 14b. Then, as illustrated in FIG. 4E, unnecessary third barrier metal 35e and second copper 35b on the second insulation film 12b are removed using CMP method. The upper surface of the second insulation film 12b, where the third barrier metal 35e and the second copper 35b are locally exposed, is thereby flattened. Therefore, the second copper 35b is embedded only into the second through-hole 14b via the third barrier metal 35e. The connection wiring 35 is formed in the through-hole 14 of the inter-layer insulation layer 12.

After the formation of the connection wiring 35, the upper layer wiring 13 made of, for example, copper is formed above the upper surface of the second insulation film 12b including the upside of the upper surface of the connection wiring 35 (upper surface of the second copper 35b) similarly to the first embodiment. The upper layer wiring 13 is formed so as to contact the upper surface of the connection wiring (upper surface of the second copper 35b). The semiconductor device 3 illustrated in FIG. 3 is thus manufactured.

As discussed above, according to the manufacturing method of the semiconductor device 3 of the second embodiment, the first barrier metal 35c satisfying the condition ER_{BM}≧ER_{I} is formed in the upper part of the first through-hole 14a that is provided in the first etching stopper film 12c and the first insulation film 12a. On condition that such first barrier metal 35c is formed, the second through-hole 14b is formed with etching under the etching condition satisfying ER_{BM}>ER_{I}. Therefore, the concaved surface S′ including the upper surface of the first insulation film 12a, and the upper surface of the first copper 15a formed below the upper surface of the first insulation film 12a or the upper surface of the first barrier metal 35c, can be exposed from the second through-hole 14b. The second copper 35b can be embedded inside the second through-hole 14b, where such concaved surface S′ is exposed, via the third barrier metal 35e. As a result, the formed connection wiring 35 can be prevented from including the space. Therefore, the connection wiring 35 with high reliability can be formed and the semiconductor device 3 with high reliability can be manufactured.

Furthermore, according to the manufacturing method of the semiconductor device 3 of the second embodiment, if a material has an etching rate faster than the etching rates of the first etching stopper film 12c and the first insulation film 12a, the material can be applied for the first barrier metal 35c. Therefore, wide variety of metal materials can be applied for the first barrier metal 35c compared with the first barrier metal 15c applied in the manufacturing method of the semiconductor device 1 of the first embodiment. This allows mitigating the restriction of etching condition, and eases the design of the semiconductor device 3.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and sprit of the inventions.

What is claimed is:

1. A manufacturing method of a semiconductor device comprising:
forming a first through-hole in a first insulation film provided on a semiconductor substrate;
embedding a first copper and a first barrier metal, in this order, into the first through-hole, an etching rate of the first barrier metal being equal to or more than an etching rate of the first insulation film;
forming a second insulation film on the first barrier metal and the first insulation film;
forming a second through-hole by removing, using etching, the second insulation film on the first barrier metal, the first barrier metal, and the first insulation film which is neighboring the first barrier metal; and
embedding a second copper into the second through-hole.

2. The manufacturing method of a semiconductor device according to claim 1, further comprising:
removing an upper layer of the first copper embedded in the first through-hole after the first copper is embedded into the first through-hole; and
embedding the first barrier metal into a space in the first through-hole, the space being generated by removing the upper layer of the first copper.

3. The manufacturing method of a semiconductor device according to claim 2, further comprising:
forming a second barrier metal on a side wall of the first through-hole after the first through-hole is formed in the first insulation film; and
embedding the first copper and the first barrier metal, in this order, into the first through-hole formed with the second barrier metal.

4. The manufacturing method of a semiconductor device according to claim 1, wherein
the first barrier metal is made of tantalum nitride or tantalum.

5. The manufacturing method of a semiconductor device according to claim 1, further comprising:
forming a second barrier metal on a side wall of the first through-hole after the first through-hole is formed in the first insulation film; and
embedding the first copper and the first barrier metal, in this order, into the first through-hole formed with the second barrier metal.

6. The manufacturing method of a semiconductor device according to claim 5, wherein
the second barrier metal is made of tantalum nitride.

7. The manufacturing method of a semiconductor device according to claim 1, wherein
a part of the first barrier metal is exposed inside the second through-hole.

8. The manufacturing method of a semiconductor device according to claim 1, wherein
the first insulation film and the second insulation film are made of SiO₂ film or SiOC film.

9. The manufacturing method of a semiconductor device according to claim 3, further comprising:
forming a third barrier metal on a side wall of the second through-hole after the second through-hole is formed; and
embedding the second copper into the second through-hole formed with the third barrier metal.

10. The manufacturing method of a semiconductor device according to claim 9, further comprising
forming a fourth barrier metal and a main wiring, in this order, on an upper surface of a second insulation film which includes an upper surface of a second copper, wherein
the main wiring is made of copper,

11. A manufacturing method of a semiconductor device comprising:
forming a first insulation film and an etching stopper film, in this order, on a semiconductor substrate;
forming a first through-hole in the etching stopper film and the first insulation film;
embedding a first copper and a first barrier metal, in this order, into the first through-hole, an etching rate of the first barrier metal being equal to or more than an etching rate of the etching stopper film and the first insulation film;
forming a second insulation film on the first barrier metal and the etching stopper film;
forming a second through-hole in the second insulation film by removing, using etching, the second insulation film on the first barrier metal, the first barrier metal, and the etching stopper film and the first insulation film which are neighboring the first barrier metal; and
embedding a second copper into the second through-hole.

12. The manufacturing method of a semiconductor device according to claim 11, wherein
the etching stopper film is made of SiN film or SiC film.

13. The manufacturing method of a semiconductor device according to claim 11, further comprising:
forming the first insulation film, the etching stopper film, and a hard mask, in this order, on a semiconductor substrate;
forming the first through-hole by reactive ion etching using the hard mask; and
removing the hard mask.

14. The manufacturing method of a semiconductor device according to claim 13, wherein
the hard mask is made of SiCN layer.

15. The manufacturing method of a semiconductor device according to claim 13, wherein
the hard mask has an opening pattern with an opening diameter larger than an opening diameter of the first through-hole.

16. The manufacturing method of a semiconductor device according to claim 11, further comprising:
forming a second barrier metal on a side wall of the first through-hole after the first through-hole is formed in the first insulation film;
embedding the first copper into the first through-hole;
flattening an upper surface of the etching stopper film by removing, using chemical mechanical polishing (CMP) method, the first copper on the etching stopper film and the second barrier metal;
removing an upper layer of the first copper embedded in the first through-hole; and
embedding the first barrier metal into a space inside the first through-hole, the space being generated by removing the upper layer of the first copper.

17. The manufacturing method of a semiconductor device according to claim 16, wherein
the upper layer of the first copper is removed by wet etching.

18. The manufacturing method of a semiconductor device according to claim 16, wherein
the flattening is performed by removing the first barrier metal on the etching stopper film using chemical mechanical polishing (CMP) method, after the first barrier metal is embedded into the space inside the first through-hole.

19. The manufacturing method of a semiconductor device according to claim 11, further comprising:
forming a third barrier metal on a side wall of the second through-hole after the second through-hole is formed; and
embedding the second copper into the second through-hole formed with the third barrier metal.

20. The manufacturing method of a semiconductor device according to claim 19, wherein
after the second copper is embedded into the second through-hole,
an upper surface of the second insulation film is flattened by removing, using chemical mechanical polishing (CMP) method, the second copper and the third barrier metal on the second insulation film.
